(19) United States
(12) Patent Application Publication
(10) Pub. No.: US 2025/0203953 A1
(43) Pub. Date: Jun. 19, 2025

(54) CHANNEL LAYER STRUCTURE FOR NANOSHEET TRANSISTORS

(71) Applicant: International Business Machines Corporation, Armonk, NY (US)

(72) Inventors: Sushant Kumar, East Greenbush, NY (US); Ruilong Xie, Niskayuna, NY (US); Julien Frougier, Albany, NY (US); Shogo Mochizuki, Mechanicville, NY (US); Alexander Reznicek, Troy, NY (US); Anna Lin, Cranbury, NJ (US); Amir M'Saad, Paradise Valley, AZ (US)

(21) Appl. No.: 18/541,854

(22) Filed: Dec. 15, 2023

(51) Int. Cl. H01L 29/10; H01L 27/088; H01L 29/06; H01L 29/165; H01L 29/423; H01L 29/775; H01L 29/786

(52) U.S. Cl. CPC H10D 30/751; H10D 30/43; H10D 30/6735; H10D 30/6757; H10D 62/121; H10D 62/299; H10D 62/822; H10D 84/83

(57) ABSTRACT

A semiconductor device comprises a plurality of gate structures stacked with a plurality of core channel layers comprising a first semiconductor material, and a plurality of cladding channel layers disposed around the plurality of gate structures and comprising a second semiconductor material different from the first semiconductor material. A source/drain region is disposed on a side of the plurality of gate structures and the plurality of core channel layers. Respective ones of a plurality of buffer semiconductor layers are disposed between respective ones of the plurality of core channel layers and the source/drain region.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming a cladding channel layer structure for nanosheet transistors.

In one embodiment, a semiconductor device includes a plurality of gate structures stacked with a plurality of core channel layers including a first semiconductor material, and a plurality of cladding channel layers disposed around the plurality of gate structures and including a second semiconductor material different from the first semiconductor material. A source/drain region is disposed on a side of the plurality of gate structures and the plurality of core channel layers. Respective ones of a plurality of buffer semiconductor layers are disposed between respective ones of the plurality of core channel layers and the source/drain region.

In another embodiment, a semiconductor device includes a plurality of core channel layers alternately stacked with a plurality of cladding channel layers, wherein the plurality of core channel layers include a first semiconductor material, and the plurality of cladding channel layers include a second semiconductor material different from the first semiconductor material. A source/drain region is disposed on a side of the plurality of core channel layers and the plurality of cladding channel layers. Respective ones of a plurality of buffer semiconductor layers are disposed between respective ones of the plurality of core channel layers and the source/drain region.

In another embodiment, a semiconductor device includes a plurality of core channel layers alternately stacked with a plurality of cladding channel layers, wherein the plurality of core channel layers include a first semiconductor material, and the plurality of cladding channel layers include a second semiconductor material different from the first semiconductor material. A first source/drain region is disposed on a first side of the plurality of core channel layers and the plurality of cladding channel layers, and a second source/drain region is disposed on a second side of the plurality of core channel layers and the plurality of cladding channel layers. Respective ones of a plurality of buffer semiconductor layers are disposed between respective ones of the plurality of core channel layers and one of the first source/drain region and the second source/drain region.

These and other features and advantages of embodiments described herein will become more apparent from the accompanying drawings and the following detailed description.

### BRIEF DESCRIPTION OF THE DRAWINGS

FIG. 1A depicts a cross-sectional view of a semiconductor structure taken perpendicular to a gate extension direction (“Cross Gate”) and illustrating semiconductor nanosheet layers, according to an embodiment of the invention.

FIG. 1B depicts a cross-sectional view of a semiconductor structure taken parallel to a gate extension direction (“Cross Nanosheet (NS)”) and illustrating semiconductor nanosheet layers, according to an embodiment of the invention.

FIG. 2A depicts a cross-sectional view of a semiconductor structure taken perpendicular to a gate extension direction following nanosheet patterning and isolation region formation, according to an embodiment of the invention.

FIG. 2B depicts a cross-sectional view of a semiconductor structure taken parallel to a gate extension direction following nanosheet patterning and isolation region formation, according to an embodiment of the invention.

FIG. 3A depicts a cross-sectional view of a semiconductor structure taken perpendicular to a gate extension direction following dummy gate formation, gate spacer formation, bottom dielectric insulator layer (BDI) formation and removal of exposed nanosheet layers, according to an embodiment of the invention.

FIG. 3B depicts a cross-sectional view of a semiconductor structure taken parallel to a gate extension direction following dummy gate formation, gate spacer formation, bottom dielectric insulator layer (BDI) formation and removal of exposed nanosheet layers, according to an embodiment of the invention.

FIG. 4A depicts a cross-sectional view of a semiconductor structure taken perpendicular to a gate extension direction following lateral etching of the nanosheet layers, according to an embodiment of the invention.

FIG. 4B depicts a cross-sectional view of a semiconductor structure taken parallel to a gate extension direction following lateral etching of the nanosheet layers, according to an embodiment of the invention.

FIG. 5A depicts a cross-sectional view of a semiconductor structure taken perpendicular to a gate extension direction following growth of differently doped epitaxial layers, according to an embodiment of the invention.

FIG. 5B depicts a cross-sectional view of a semiconductor structure taken parallel to a gate extension direction following growth of differently doped epitaxial layers, according to an embodiment of the invention.

FIG. 6A depicts a cross-sectional view of a semiconductor structure taken perpendicular to a gate extension direction following deposition of an inter-layer dielectric (ILD layer), according to an embodiment of the invention.

FIG. 6B depicts a cross-sectional view of a semiconductor structure taken parallel to a gate extension direction following deposition of an ILD layer, according to an embodiment of the invention.

FIG. 7A depicts a cross-sectional view of a semiconductor structure taken perpendicular to a gate extension direction following dummy gate and sacrificial layer removal, according to an embodiment of the invention.

FIG. 7B depicts a cross-sectional view of a semiconductor structure taken parallel to a gate extension direction following dummy gate and sacrificial layer removal, according to an embodiment of the invention.

FIG. 8A depicts a cross-sectional view of a semiconductor structure taken perpendicular to a gate extension direction following isotropic trimming of channel layers, according to an embodiment of the invention.

FIG. 8B depicts a cross-sectional view of a semiconductor structure taken parallel to a gate extension direction following isotropic trimming of channel layers, according to an embodiment of the invention.

FIG. 9A depicts a cross-sectional view of a semiconductor structure taken perpendicular to a gate extension direction following epitaxial growth of cladding channel layers, according to an embodiment of the invention.

FIG. 9B depicts a cross-sectional view of a semiconductor structure taken parallel to a gate extension direction following epitaxial growth of cladding channel layers, according to an embodiment of the invention.

FIG. 10A depicts a cross-sectional view of a semiconductor structure taken perpendicular to a gate extension direction following replacement metal gate (RMG) and contact formation, according to an embodiment of the invention.

FIG. 10B depicts a cross-sectional view of a semiconductor structure taken parallel to a gate extension direction following replacement metal gate (RMG) and contact formation, according to an embodiment of the invention.

### DETAILED DESCRIPTION

Illustrative embodiments of the invention may be described herein in the context of illustrative methods for forming a cladding channel layer structure for nanosheet transistors, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

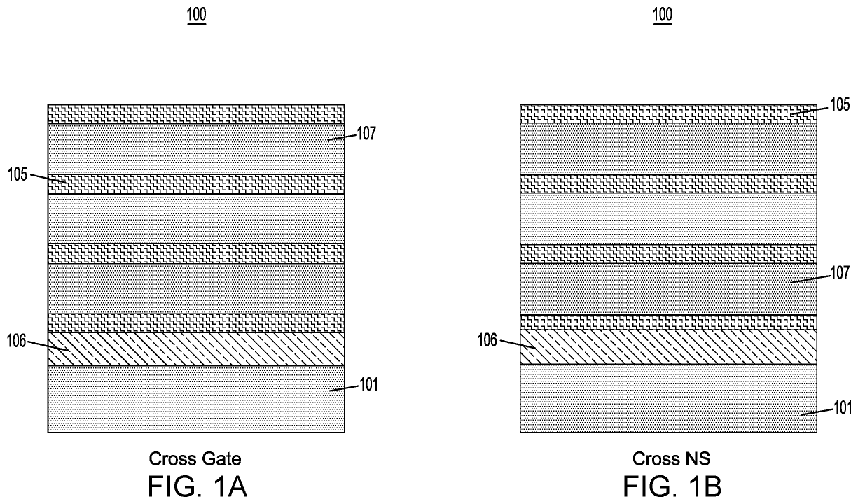

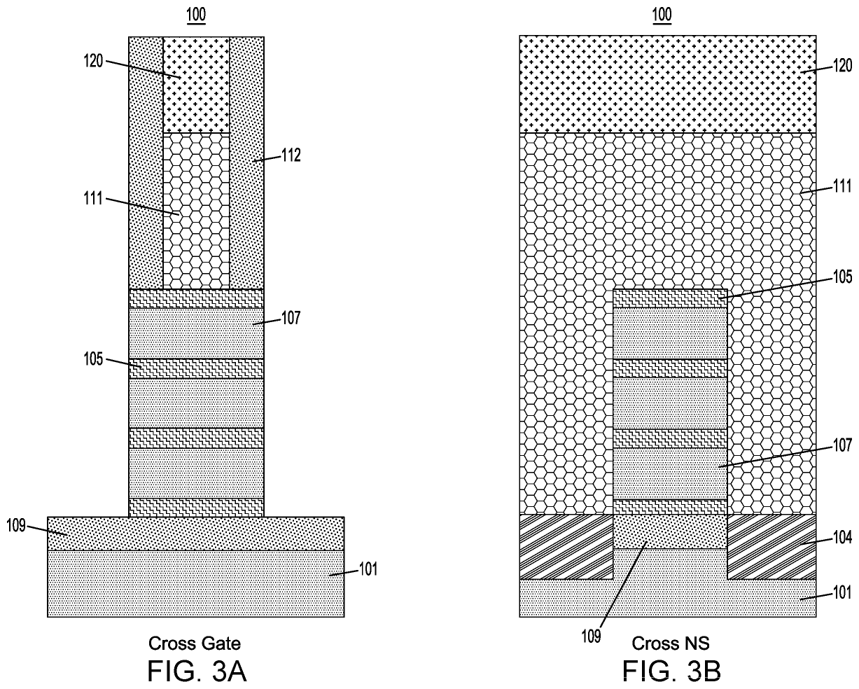

Referring to FIG. 1, a semiconductor structure 100 includes a stacked structure of sacrificial layers 105 and core channel layers 107. In an illustrative embodiment, the sacrificial layers 105 include silicon germanium (SiGe) and the core channel layers 107 include silicon. In illustrative embodiments, the sacrificial layers 105 include a germanium concentration of about 25% or 30% (e.g., SiGe25 or SiGe30), but the embodiments are not necessarily limited to SiGe25 or SiGe30 for the sacrificial layers 105. The lowermost sacrificial layer is formed on an additional sacrificial layer 106 including, for example, SiGe with a different concentration of germanium than that of the sacrificial layers 105. For example, the additional sacrificial layer 106 has, but is not necessarily limited to, a germanium concentration of about 55% (e.g., SiGe55). As explained in more detail herein, the additional sacrificial layer 106 has a different concentration of germanium than the sacrificial layers 105 so that the additional sacrificial layer 106 can be selectively etched and removed with respect to sacrificial layers 105 when forming a bottom dielectric isolation (BDI) layer (see, e.g., FIGS. 3A and 3B including BDI layer 109).

A semiconductor substrate 101 includes semiconductor material including, but not limited to, silicon (Si), III-V, II-V compound semiconductor materials or other like semiconductor materials. In addition, multiple layers of the semiconductor materials can be used as the semiconductor material of the semiconductor substrate.

The sacrificial layers 105 and core channel layers 107 are epitaxially grown in an alternating and stacked configuration on the additional sacrificial layer 106. A first sacrificial layer 105 is followed by a first core channel layer 107 on the first sacrificial layer 105, which is followed by a second sacrificial layer on the first core channel layer 107, and so on. As can be understood, the sacrificial layers 105 and core channel layers 107 are epitaxially grown from their corresponding underlying semiconductor layers.

While four sacrificial layers 105 and three core channel layers 107 are shown, the embodiments of the present invention are not necessarily limited to the shown number of sacrificial layers 105 and core channel layers 107, and there may be more or less layers in the same alternating configuration depending on design constraints. The sacrificial layers 105, as described further herein, are eventually removed and replaced by gate structures.

Although SiGe is described as a sacrificial material for sacrificial layers 105, other materials can be used as long as the sacrificial layers 105 have the property of being able to be removed selectively compared to the material of the core channel layers 107.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

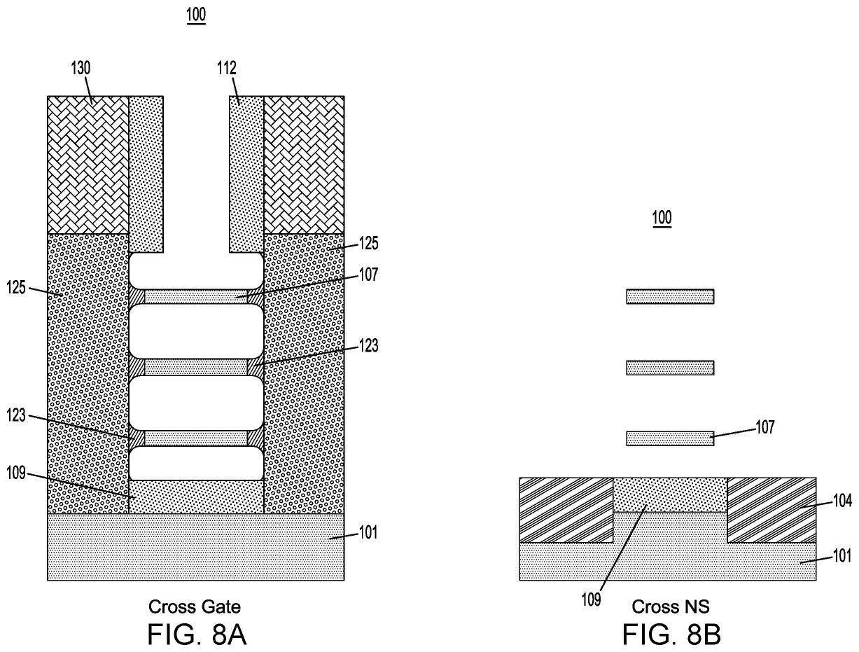

In a non-limiting illustrative embodiment, a height (e.g., vertical thickness) of the sacrificial layers 105 can be in the range of about 6 nm to about 15 nm depending on the application of the device. Also, in a non-limiting illustrative embodiment, a height (e.g., vertical thickness) of the core channel layers 107 can be in the range of about 9 nm to about 20 nm depending on the desired process and application. Due to subsequent isotropic trimming of the core channel layers 107 as described in more detail in connection with FIGS. 8A and 8B, the initial height (e.g., vertical thickness) of the core channel layers 107 is larger than that of the sacrificial layers 105. In accordance with an embodiment of the present invention, each of the core channel layers 107 has the same or substantially the same composition and size as each other, and each of the sacrificial layers 105 has the same or substantially the same composition and size as each other.

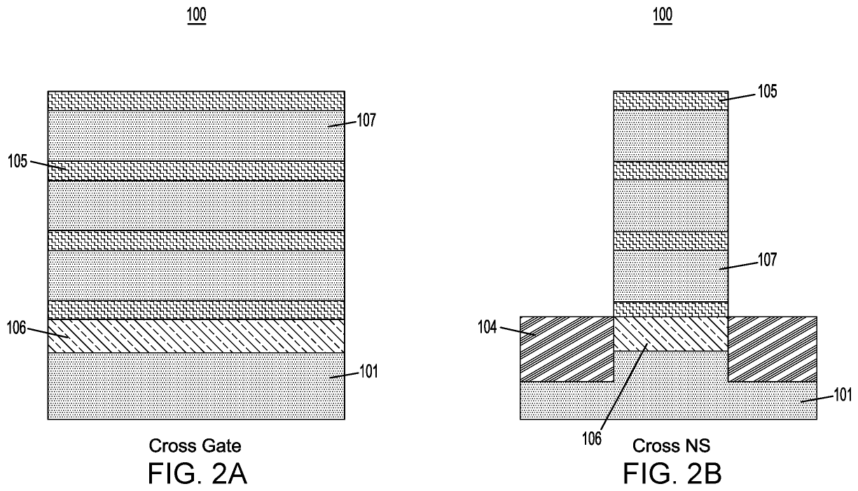

Referring to FIGS. 2A and 2B, portions of the nanosheet stacks comprising the sacrificial layers 105 and core channel layers 107 are removed, portions of the additional sacrificial layer 106 are removed and portions of the semiconductor substrate 101 are recessed. Isolation regions 104 (e.g., shallow trench isolation (STI) regions) are formed adjacent the patterned nanosheet stack, and remaining portions of the additional sacrificial layer 106 and the semiconductor substrate 101. The dielectric material of the isolation regions may include, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

Referring to FIGS. 3A and 3B, a dummy gate portion 111 is formed on the uppermost sacrificial layer 105 and around the stacked nanosheet configuration of the sacrificial layers 105 and core channel layers 107. The dummy gate portion 111 includes, but is not necessarily limited to, an amorphous silicon (a-Si) layer. The dummy gate portion 111 is deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess dummy gate material, and pattern the deposited layer. A hardmask layer 120 is formed on the dummy gate portion 111. The hardmask layer 120 includes, for example, a nitride such as silicon nitride (SiN) or other nitride material.

A remaining portion of the additional sacrificial layer 106 between the lowermost sacrificial layer 105 and semiconductor substrate 101 is removed using, for example, an aqueous solution containing ammonium hydroxide (NH₄OH) and hydrogen peroxide (H₂O₂) or a gas containing hydrogen fluoride (HF) to selectively etch the additional sacrificial layer 106 with respect to the semiconductor substrate 101, the sacrificial layers 105 and the core channel layers 107. The selective etching removes the additional sacrificial layer 106 to form a vacant area where the BDI layer 109 is formed.

Dielectric material is deposited in place of the additional sacrificial layer 106 using deposition techniques such as, for example, CVD, PECVD, RFCVD, PVD, ALD, MBD, PLD, and/or LSMCD, followed by an etch back to form the BDI layer 109 on the semiconductor substrate 101 in place of the additional sacrificial layer 106. The BDI layer 109 may include, for example, silicon oxide (SiOₓ) (where x is for example, 2, 1.99 or 2.01), silicon oxycarbide (SiOC), SiN, silicon oxynitride (SiON), silicon-carbon-nitride (SiCN), boron nitride (BN), silicon boron nitride (SiBN), silicoboron carbonitride (SiBCN), silicon oxycarbonitride (SiOCN) or some other dielectric. The BDI layer 109 is under a bottom surface of the lowermost sacrificial layer 105.

Gate spacers 112 are formed on sides of the hardmask layer 120 and dummy gate portion 111 by one or more of the deposition techniques noted in connection with deposition of the dummy gate material. The spacer material can include for example, one or more dielectrics, including, but not necessarily limited to, SIN, SiON, SiOC, SiCN, BN, SiBN, SiBCN, SiOCN, SiOₓ, and combinations thereof. According to an embodiment, the hardmask layer 120 and gate spacers 112 can be the same material or different materials. The gate spacers 112 can be formed by any suitable techniques such as deposition followed by directional etching. Deposition may include but is not limited to, ALD or CVD. Directional etching may include but is not limited to, reactive ion etching (RIE).

Exposed portions of the stacked sacrificial layers 105 and core channel layers 107, which are not under the hardmask layer 120, gate spacers 112 and dummy gate portion 111, are removed using, for example, an etching process, such as RIE, where the hardmask layer 120, gate spacers 112 and dummy gate portion 111 are used as a mask. The portions of the stacked structure of sacrificial layers 105 and core channel layers 107 under the hardmask layer 120, gate spacers 112 and under the dummy gate portion 111 remain after the etching process, and portions of the sacrificial layers 105 and core channel layers 107 in areas that correspond to where source/drain regions will be formed are removed. The process for removal of the exposed portions of the sacrificial layers 105 and core channel layers 107 includes, for example, using CF₄ gas to selectively remove SiGe and a RIE process with H₂/CF₄ plasma to remove silicon.

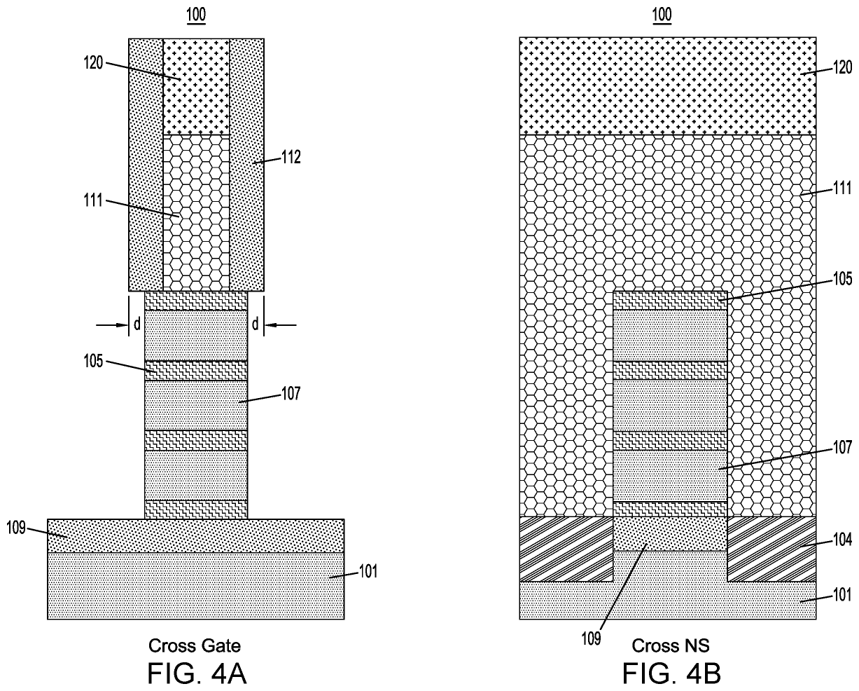

Referring to FIGS. 4A and 4B, following removal of the exposed portions of the stacked sacrificial layers 105 and core channel layers 107 not under the hardmask layer 120, gate spacers 112 and dummy gate portion 111, lateral etching of the remaining stacked sacrificial layers 105 and core channel layers 107 is performed. As can be seen, the lateral etching removes side portions of the stacked sacrificial layers 105 and core channel layers 107 so that the stacked structure of sacrificial layers 105 and core channel layers 107 is recessed to a depth d with respect to the outer surfaces of the gate spacers 112. The etching process selectively removes the semiconductor materials of the sacrificial layers 105 and core channel layers 107 with respect to the dielectric materials of the BDI layer 109 and the gate spacers 112, and may include, for example, an isotropic dry etch process.

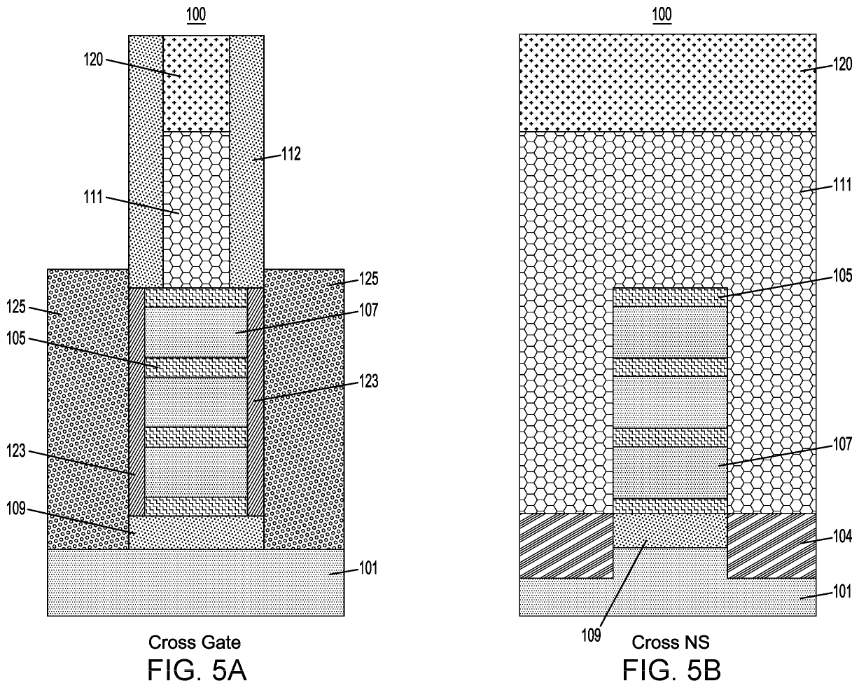

Referring to FIGS. 5A and 5B, following the lateral etching of the remaining stacked sacrificial layers 105 and core channel layers 107, silicon buffer layers 123 are epitaxially grown from the exposed side surfaces of the sacrificial layers 105 and core channel layers 107 to fill in the spaces left by the laterally recessed portions of the stacked structure of sacrificial layers 105 and core channel layers 107. In an illustrative embodiment, the silicon buffer layers 123 are lightly doped with a p-type dopant (e.g., boron) at a concentration of about 1×10¹⁸/cm³ to 9×10²⁰/cm³.

Following epitaxial growth and doping of the silicon buffer layers 123, exposed portions of the BDI layer 109 are removed to expose portions of the semiconductor substrate 101. The process for removal of the exposed portions of the BDI layer 109 includes, for example, using CF₄/H₂, CF₄/O₂/N₂, SF₆/O₂/N₂, SF₆/CH₄/N₂ and/or SF₆/CH₄/N₂/O₂.

Source/drain regions 125 are grown from and contact exposed sides of the silicon buffer layers 123, and from the exposed top surface of the semiconductor substrate 101 (e.g., silicon) not covered by the BDI layer 109. According to a non-limiting embodiment of the present invention, the conditions of the epitaxial growth process for the source/drain region 125 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr.

In an illustrative embodiment, the source/drain regions 125 correspond to a p-type transistor (e.g., pFET) and can include in-situ boron doped (ISBD) SiGe. According to an embodiment, the source/drain regions 125 are heavily doped with a dopant at concentrations of about 1×1019/cm³ to about 3×1021/cm³. Other doping methods include, for example, ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (TI).

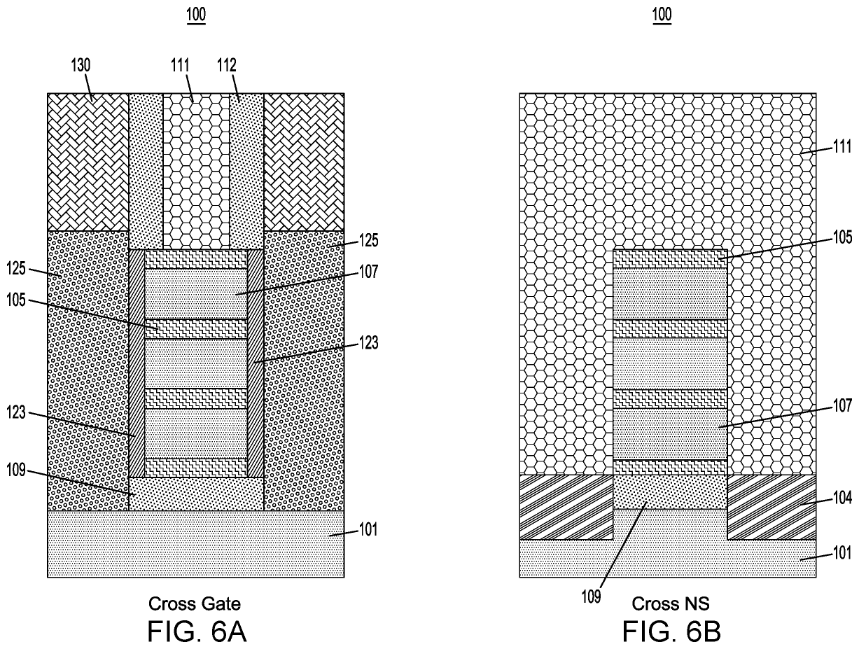

Referring to FIGS. 6A and 6B, an inter-layer dielectric (ILD) layer 130 is deposited to fill in portions on and around the source/drain regions 125. The ILD layer 130 is deposited using deposition techniques such as, for example, CVD, PECVD, RFCVD, PVD, ALD, MBD, PLD, and/or LSMCD, followed by a planarization process, such as, CMP to remove excess portions of the ILD layer 130 deposited on top of the hardmask layer 120 and gate spacers 112, and to remove the hardmask layer 120 and portions of the gate spacers 112 to expose the dummy gate portion 111. The ILD layer 130 may include, for example, SiOₓ, SiOC, SiOCN or some other dielectric.

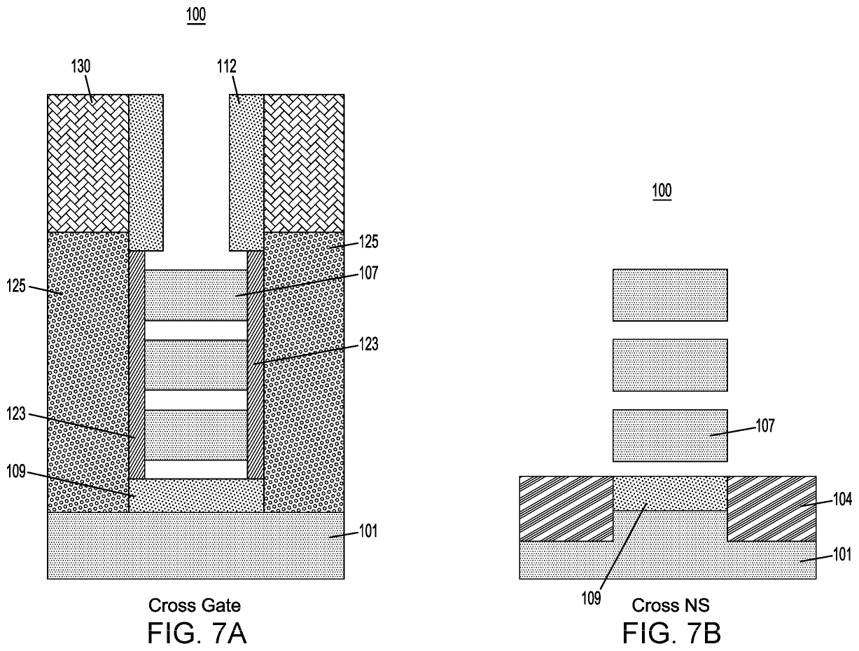

Referring to FIGS. 7A and 7B, the dummy gate portion 111 is selectively removed to create a vacant area where a gate structure will be formed in place of the dummy gate portion 111. The selective removal can be performed using, for example, hot ammonia to remove a-Si. In addition, the sacrificial layers 105 are selectively removed to create vacant areas where gate structures will be formed in place of the sacrificial layers 105. The sacrificial layers 105 are selectively removed with respect to the core channel layers 107, the silicon buffer layers 123 and the BDI layer 109. The selective removal can be performed using, for example, a dry HCl etch. In illustrative embodiments, the silicon buffer layers 123 and the BDI layer 109 protect the source/drain regions 125 (which include SiGe) from being removed during removal of sacrificial layers 105 comprising SiGe.

Referring to FIGS. 8A and 8B, following removal of the dummy gate portions 111 and sacrificial layers 105, isotropic trimming of the core channel layers 107 and the silicon buffer layers 123 is performed. As can be seen in FIGS. 8A and 8B, the isotropic trimming reduces vertical thicknesses of the core channel layers 107 and the silicon buffer layers 123 to increase a distance between core channel layers 107. In an illustrative embodiment, the vertical thickness of the core channel layers 107 is reduced to about 4 nm to about 7 nm.

As can be seen in FIGS. 8A and 8B, the respective ones of the silicon buffer layers 123 are disposed between an end of a core channel layer 107 and a source/drain region 125 such that a first side of a silicon buffer layer 123 contacts an end of a core channel layer 107 and a second side of the silicon buffer layer 123 contacts a side of the source/drain region 125. Vertical thickness of respective ones of the silicon buffer layers 123 varies between ends of respective ones of the core channel layers 107 and the source/drain regions 125. For example, an area of a first portion of a silicon buffer layer 123 contacting a core channel layer 107 is smaller than an area of a second portion of the silicon buffer layer 123 contacting the source/drain region 125.

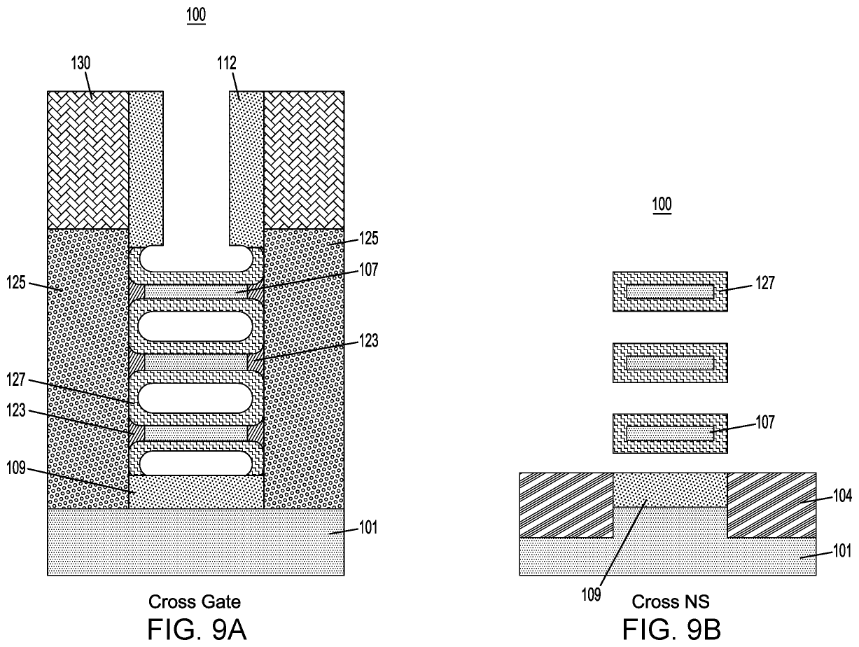

Referring to FIGS. 9A and 9B, cladding channel layers 127 are epitaxially grown on and around the core channel layers 107 and silicon buffer layers 123. The cladding channel layers 107 are grown from exposed surfaces of the core channel layers 107, silicon buffer layers 123 and source/drain regions 125. In illustrative embodiments, the channel cladding layers 127 include SiGe and have a thickness of about 1 nm to about 8 nm.

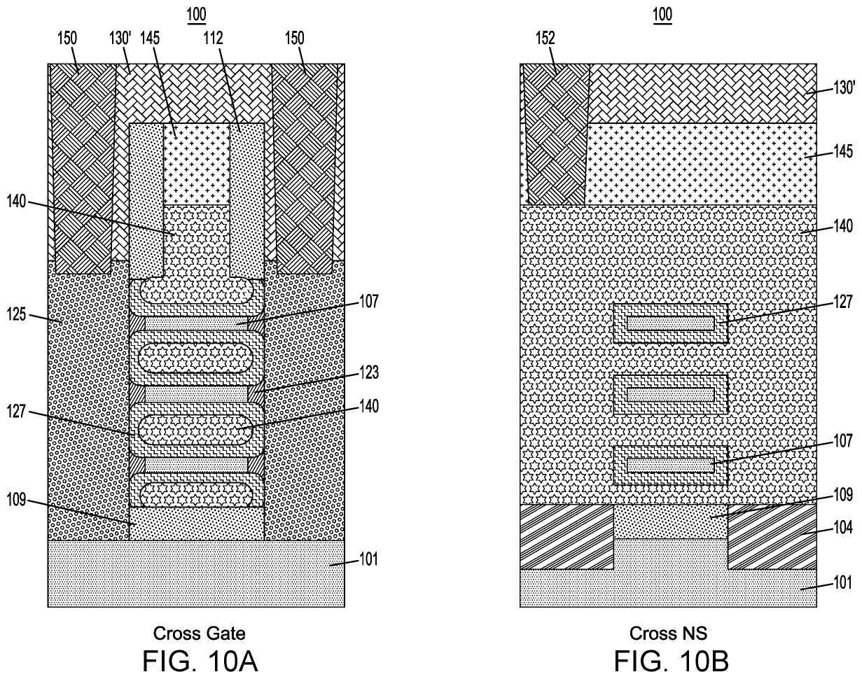

The cladding channel layers 127 are formed from a different semiconductor material (e.g., SiGe) than that of the core channel layers 107 (e.g., silicon). Two respective cladding channel layers 127 are disposed on opposite surfaces of a core channel layer 107 (e.g., on top and bottom surfaces of the core channel layer 107). As can be seen, at least some of the cladding channel layers form a closed loop around a vacant area between core channel layers 107 that will be filled with gate structures 140 (see FIGS. 10A and 10B). As shown in FIG. 9A, the cladding channel layers 127 include vertical sides with surfaces contacting the source/drain regions 125, and the combination of vertical and horizontal sides form the closed loops. As can be seen in FIG. 9A, the combination of multiple cladding channel layers 127 envelope (e.g., surround) respective core channel layers 107 on all sides thereof. A pFET device with SiGe based cladding channel layers 127 can have higher channel mobility than conventional pFET devices. The illustrative embodiments maximize connections between SiGe based source/drain regions 125 and SiGe based cladding layers 127 by forming cladding epitaxial layers directly on exposed source/drain epitaxial layers, which removes any Schottky barrier between the S/D regions and channels, resulting in improved device performance.

Referring to FIGS. 10A and 10B, gate structures 140, including, for example, gate and dielectric portions, are formed in the vacant portions that are at least partially enclosed by the cladding channel layers 127 and that were formed by the removal of the dummy gate portion 111 and the sacrificial layers 105, and by the isotropic trimming of the core channel layers 107 and silicon buffer layers 123. In illustrative embodiments, each gate structure 140 includes a gate dielectric layer such as, for example, a high-K dielectric layer including, but not necessarily limited to, HfO₂ (hafnium oxide), ZrO₂ (zirconium dioxide), hafnium zirconium oxide, Al2O3 (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate structures 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

The cladding channel layers 127 are disposed around the gate structures 140. At least some of the cladding channel layers 127 form a closed loop around a gate structure 140. Some of the cladding channel layers 127 surround a gate structure 140 on all sides (e.g., middle cladding channel layers 127), and other cladding channel layers 127 surround a gate structure 140 on 3 sides (e.g., top and bottom cladding channel layers 127).

In addition to the uppermost gate structure 140 between the gate spacers 112, a self-aligned contact (SAC) cap layer 145 is also formed in place of the dummy gate portion 111. The SAC cap layer 145 includes, but is not necessarily limited to, silicon SiN, SiBN, SiBCN or SiOCN. According to an embodiment of the present invention, the SAC cap layer 145 is deposited using, for example, deposition techniques including, but not limited to, CVD, PECVD, RFCVD, PVD, ALD, MLD, MBD, PLD, LSMCD, sputtering, and/or plating, followed by a planarization process, such as, for example, CMP.

As shown in FIGS. 10A and 10B, additional ILD material is deposited to form an additional ILD layer 130′ on top of the ILD layer 130. The additional ILD layer 130′ is deposited using the same or similar deposition techniques and includes the same or similar material to that of the ILD layer 130. Source/drain contacts 150 and a gate contact 152 are formed in the additional ILD layer 130′ and the ILD layer 130 to contact the source/drain regions 125. According to illustrative embodiments, openings corresponding to locations of the source/drain contacts 150 and gate contact 152 are formed in the additional ILD layer 130′ and the ILD layer 130 using, for example, a RIE process. In more detail, portions of the additional ILD layer 130′ exposed via a hardmask (not shown) are etched to form the source/drain contact and gate contact openings in the additional ILD layer 130′ and the ILD layer 130, which are then filled with conductive material (e.g., metal).

For example, metal layers are deposited in the source/drain contact and gate contact openings to form the source/drain contacts 150 and the gate contact 152. The metal layers include, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the additional ILD layer 130′.

The source/drain contacts 150 contact the source/drain regions 125 and the gate contact 152 contacts a gate structure 140. The source/drain contacts 150 and gate contact 152 extend through the additional ILD layer 130′ and the ILD layer 130 to land on and contact the corresponding source/drain regions 125 and gate structure 140.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming a cladding channel layer structure for nanosheet transistors. Nanosheet gate-all-around (GAA) transistors have demonstrated better electrostatics and short channel control than FinFETs. However, GAA PFETs show poorer performance than GAA NFETs. Nanosheet architecture with a SiGe channel overcomes that problem through improved mobility and exhibits advantages of threshold voltage modulation and improved negative-bias temperature instability (NBTI). However, current integration schemes for nanosheet transistors with SiGe channels and source/drain regions exhibit band offset, which leads to performance degradation. This occurs because of the persistence of a region around inner spacers between a source/drain and channel regions. The region around the inner spacers is not sufficiently doped and leads to the formation of a barrier. In an effort to address the problems with conventional approaches, the illustrative embodiments advantageously provide a nanosheet structure that includes channel cladding layers disposed around gate structures between the gate structures and SiGe source/drain region. The channel cladding layer includes SiGe. In addition, a lightly doped buffer semiconductor region (e.g., silicon) is disposed between core channel layers and the SiGe source/drain regions. In illustrative embodiment, the SiGe source/drain regions are heavily doped with boron. Accordingly, the configuration including the channel cladding layers and lightly doped buffer semiconductor layers of the illustrative embodiments advantageously prevents insufficiently doped regions that may result in barriers.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as +5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a plurality of gate structures stacked with a plurality of core channel layers comprising a first semiconductor material;
a plurality of cladding channel layers disposed around the plurality of gate structures and comprising a second semiconductor material different from the first semiconductor material;
a source/drain region disposed on a side of the plurality of gate structures and the plurality of core channel layers; and
a plurality of buffer semiconductor layers, wherein respective ones of the plurality of buffer semiconductor layers are disposed between respective ones of the plurality of core channel layers and the source/drain region.

2. The semiconductor device of claim 1, wherein the first semiconductor material comprises silicon and the second semiconductor material comprises silicon germanium.

3. The semiconductor device of claim 2, wherein the source/drain region corresponds to a p-type transistor and comprises doped silicon germanium.

4. The semiconductor device of claim 1, wherein at least one of the plurality of cladding channel layers surrounds a gate structure of the plurality of gate structures.

5. The semiconductor device of claim 1, wherein the plurality of cladding channel layers contact the source/drain region.

6. The semiconductor device of claim 1, wherein the respective ones of the plurality of buffer semiconductor layers contact the source/drain region.

7. The semiconductor device of claim 6, wherein the respective ones of the plurality of buffer semiconductor layers contact the respective ones of the plurality of core channel layers.

8. The semiconductor device of claim 7, wherein an area of a first portion of a buffer semiconductor layer of the plurality of buffer semiconductor layers contacting a core channel layer is smaller than an area of a second portion of the buffer semiconductor layer contacting the source/drain region.

9. The semiconductor device of claim 1, wherein the plurality of buffer semiconductor layers comprise the first semiconductor material.

10. The semiconductor device of claim 1, wherein an area of a first portion of at least one buffer semiconductor layer of the plurality of buffer semiconductor layers on a core channel layer of the plurality of core channel layers is smaller than an area of a second portion of the at least one buffer semiconductor layer on the source/drain region.

11. The semiconductor device of claim 1, wherein respective cladding channel layers layers of the plurality of cladding channel layers are disposed on opposite surfaces of a core channel layer of the plurality of core channel layers.

12. The semiconductor device of claim 1, wherein the plurality of cladding channel layers are disposed directly on the source/drain region.

13. A semiconductor device comprising:
a plurality of core channel layers alternately stacked with a plurality of cladding channel layers, wherein the plurality of core channel layers comprise a first semiconductor material and the plurality of cladding channel layers comprise a second semiconductor material different from the first semiconductor material;
a source/drain region disposed on a side of the plurality of core channel layers and the plurality of cladding channel layers; and
a plurality of buffer semiconductor layers, wherein respective ones of the plurality of buffer semiconductor layers are disposed between respective ones of the plurality of core channel layers and the source/drain region.

14. The semiconductor device of claim 13, wherein the first semiconductor material comprises silicon and the second semiconductor material comprises silicon germanium.

15. The semiconductor device of claim 14, wherein the source/drain region corresponds to a p-type transistor and comprises doped silicon germanium.

16. The semiconductor device of claim 13, wherein respective ones of the plurality of cladding channel layers are disposed around respective gate structures of a plurality of gate structures.

17. The semiconductor device of claim 13, wherein the respective ones of the plurality of buffer semiconductor layers contact the source/drain region and the respective ones of the plurality of core channel layers.

18. A semiconductor device comprising:
a plurality of core channel layers alternately stacked with a plurality of cladding channel layers, wherein the plurality of core channel layers comprise a first semiconductor material and the plurality of cladding channel layers comprise a second semiconductor material different from the first semiconductor material;
a first source/drain region disposed on a first side of the plurality of core channel layers and the plurality of cladding channel layers, and a second source/drain region disposed on a second side of the plurality of core channel layers and the plurality of cladding channel layers; and
a plurality of buffer semiconductor layers, wherein respective ones of the plurality of buffer semiconductor layers are disposed between respective ones of the plurality of core channel layers and one of the first source/drain region and the second source/drain region.

19. The semiconductor device of claim 18, wherein the first semiconductor material comprises silicon and the second semiconductor material comprises silicon germanium.

20. The semiconductor device of claim 19, wherein the plurality of buffer semiconductor layers comprise the first semiconductor material.
